(19) United States
(12) Patent Application Publication
(10) Pub. No.: US 2026/0095021 A1
(43) Pub. Date: Apr. 2, 2026

(54) METHOD OF MANUFACTURING LIGHT-EMITTING DEVICE

(71) Applicant: Nichia Corporation, Anan-shi (JP)

(72) Inventors: Kenji OZEKI, Tokushima-shi (JP); Yu NARIMATSU, Komatsushima-shi (JP)

(73) Assignee: Nichia Corporation, Anan-shi (JP)

(21) Appl. No.: 19/335,188

(22) Filed: Sep. 22, 2025

(30) Foreign Application Priority Data
Sep. 27, 2024 (JP) 2024-169476

(51) Int. Cl. H01S 5/0236; H01S 5/02257

(52) U.S. Cl. CPC H01S 5/0236; H01S 5/02257

(57) ABSTRACT

A method of manufacturing a light-emitting device includes: preparing a light-emitting element; preparing a light-transmissive member; disposing a first bonding member that is uncured on at least a portion of an outer peripheral region of the upper surface of the light-emitting element; disposing a second bonding member that is uncured on a portion of the upper surface of the light-emitting element that is exposed from the first bonding member, wherein a viscosity of the second bonding member that is uncured is lower than a viscosity of the first bonding member that is uncured; spreading the first bonding member and/or the second bonding member in an outer peripheral region of the lower surface of the light-transmissive member by pressing the first bonding member and the second bonding member by the lower surface of the light-transmissive member; and curing the first bonding member and the second bonding member.

### CROSS-REFERENCE TO RELATED APPLICATION

This application claims priority to Japanese Patent Application No. 2024-169476, filed on Sep. 27, 2024, the disclosure of which is hereby incorporated herein by reference in its entirety.

### TECHNICAL FIELD

The present disclosure relates to a method of manufacturing a light-emitting device.

### BACKGROUND

There is a known light-emitting device including a substrate, a light-emitting element mounted on the substrate, a transparent material layer disposed on the light-emitting element, a plate-shaped optical layer mounted on the transparent material layer, and a reflective material layer disposed around the light-emitting element and the transparent material layer. In this light-emitting device, a lower surface of the plate-shaped optical layer is larger than an upper surface of the light-emitting element, and the reflective material layer forms an inclined surface connecting a lower end of a lateral surface of the light-emitting element and a lateral surface of the plate-shaped optical layer. (See for example, Japanese Patent Publication No. 2012-004303).

A method of manufacturing such a light-emitting device includes, for example, a first step of forming an uncured transparent material layer having an inclined lateral surface between the light-emitting element and the plate-shaped optical layer and then curing the transparent material layer, and a second step of forming a reflective material layer having an inclined lateral surface along the inclined lateral surface of the transparent material layer by filling a non-conductive reflective material around the transparent material layer and curing the non-conductive reflective material.

### SUMMARY

An object of the present disclosure is to provide a method of manufacturing a light-emitting device with less brightness unevenness, and a light-emitting device with less brightness unevenness.

A method of manufacturing a light-emitting device according to an embodiment of the present disclosure includes: preparing a light-emitting element; preparing a light-transmissive member having a lower surface having a larger area than an upper surface of the light-emitting element; disposing first bonding members that are uncured on at least a portion of an outer peripheral region of the upper surface of the light-emitting element; disposing a second bonding member that is uncured on the upper surface of the light-emitting element exposed from the first bonding members, wherein a viscosity of the second bonding member that is uncured is lower than a viscosity of the first bonding member that is uncured; spreading the first bonding members and/or the second bonding member in an outer peripheral region of the lower surface of the light-transmissive member by pressing the first bonding members and the second bonding member by the lower surface of the light-transmissive member; and curing the first bonding members and the second bonding member.

A light-emitting device according to an embodiment of the present disclosure includes: a light-emitting element; a light-transmissive member; and a bonding member disposed between an upper surface of the light-emitting element and a lower surface of the light-transmissive member, the bonding member being in contact with an entirety of the lower surface of the light-transmissive member, in which the bonding member contains light scattering particles, and the bonding member at a position not overlapping the light-emitting element in a top view includes a region having a higher concentration of the light scattering particles than the bonding member at a position overlapping the light-emitting element in a top view.

According to an embodiment of the present disclosure, it is possible to provide a method of manufacturing a light-emitting device with less brightness unevenness, and a light-emitting device with less brightness unevenness.

### BRIEF DESCRIPTION OF DRAWINGS

FIG. 1 is a schematic perspective view illustrating a light-emitting device according to the present embodiment.

FIG. 2 is a schematic cross-sectional view taken along line II-II in FIG. 1.

FIG. 3 is a schematic view of a light-emitting element, a bonding member, and a light-transmissive member of FIG. 1 as viewed from an upper surface side of the light-transmissive member.

FIG. 4A is a schematic cross-sectional view illustrating an example of a manufacturing process of the light-emitting device according to the present embodiment.

FIG. 4B is a schematic cross-sectional view illustrating an example of the manufacturing process of the light-emitting device according to the present embodiment.

FIG. 4C is a schematic cross-sectional view illustrating an example of the manufacturing process of the light-emitting device according to the present embodiment.

FIG. 4D is a schematic view of the light-emitting element and first bonding members in FIG. 4C as viewed from the upper surface side of the light-emitting element.

FIG. 4E is a schematic cross-sectional view illustrating an example of the manufacturing process of the light-emitting device according to the present embodiment.

FIG. 4F is a schematic view of the light-emitting element, the first bonding members, and a second bonding member in FIG. 4E as viewed from the upper surface side of the light-emitting element.

FIG. 4G is a schematic cross-sectional view illustrating an example of the manufacturing process of the light-emitting device according to the present embodiment.

FIG. 4H is a schematic view of the light-emitting element, the first bonding members, and the second bonding member in FIG. 4G as viewed from the upper surface side of the light-emitting element.

FIG. 4I is a schematic cross-sectional view illustrating an example of the manufacturing process of the light-emitting device according to the present embodiment.

FIG. 4J is a schematic cross-sectional view illustrating an example of the manufacturing process of the light-emitting device according to the present embodiment.

FIG. 4K is a schematic view of the light-emitting element, the first bonding members, the second bonding member, and the light-transmissive member in FIG. 4J as viewed from the upper surface side of the light-transmissive member.

FIG. 4L is a schematic cross-sectional view illustrating an example of the manufacturing process of the light-emitting device according to the present embodiment.

FIG. 4M is a schematic cross-sectional view illustrating an example of the manufacturing process of the light-emitting device according to the present embodiment.

FIG. 5 is an example of a manufacturing process of a light-emitting device according to Modified Example 1 of the present embodiment, and is a schematic view of the light-emitting element, the first bonding members, and the second bonding members as viewed from the upper surface side of the light-emitting element.

FIG. 6A is a schematic cross-sectional view illustrating an example of a manufacturing process of the light-emitting device according to Modified Example 2 of the present embodiment.

FIG. 6B is a schematic view of the light-emitting element, the first bonding members, the second bonding member, and the light-transmissive member in FIG. 6A as viewed from the upper surface side of the light-transmissive member.

FIG. 7A is an example of a manufacturing process of a light-emitting device according to Modified Example 3 of the present embodiment, and is a schematic view of the light-emitting element and the first bonding members as viewed from the upper surface side of the light-emitting element.

FIG. 7B is an example of the manufacturing process of the light-emitting device according to Modified Example 3 of the present embodiment, and is a schematic view of the light-emitting element, the first bonding members, and the second bonding member as viewed from the upper surface side of the light-emitting element.

FIG. 7C is an example of the manufacturing process of the light-emitting device according to Modified Example 3 of the present embodiment, and is a schematic view of the light-emitting element, the first bonding members, and the second bonding member as viewed from the upper surface side of the light-emitting element.

### DETAILED DESCRIPTION

Hereinafter, a manufacturing method according to an embodiment of the present invention and a light-emitting device obtained by the manufacturing method (hereinafter, may be referred to as a “light-emitting device according to an embodiment”) will be described with reference to the drawings. In the following description, terms indicating a specific direction or position (for example, “upper,” “lower,” and other terms including those terms) are used as necessary. The use of those terms, however, is to facilitate understanding of the invention with reference to the drawings, and the technical scope of the present invention is not limited by the meanings of those terms. The same reference characters appearing in a plurality of drawings indicate identical or equivalent parts or members.

Further, the following embodiments exemplify a light-emitting device and the like for embodying the technical concepts of the present invention, but the present invention is not limited to the described embodiments. The dimensions, materials, shapes, relative arrangements, and the like of constituent components described below are not intended to limit the scope of the present invention to those alone, but are intended to provide an example, unless otherwise specified. The contents described in an embodiment can be applied to any of the other embodiments and modified examples. The sizes, the positional relationship, and the like of the members illustrated in the drawings may be exaggerated to clarify the explanation. Furthermore, to avoid excessive complication of the drawings, a schematic view in which some elements are not illustrated may be used, or an end view illustrating only a cutting surface may be used as a cross-sectional view. In addition, even in a case in which the size or shape of some members is changed by processing, or the size or shape of some members is changed by pressing, the same names as those before the change may still be used for their descriptions.

### Light-Emitting Device 1 According to Present Embodiment

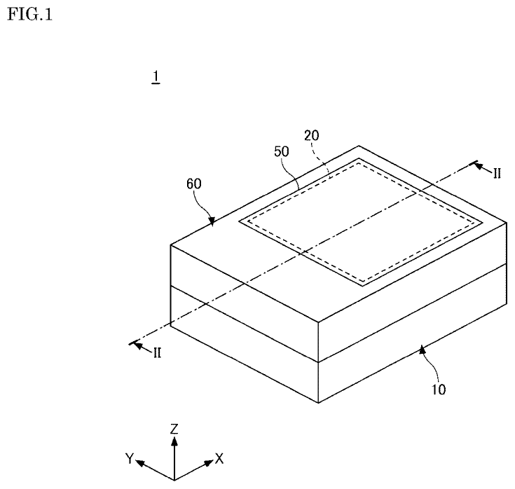

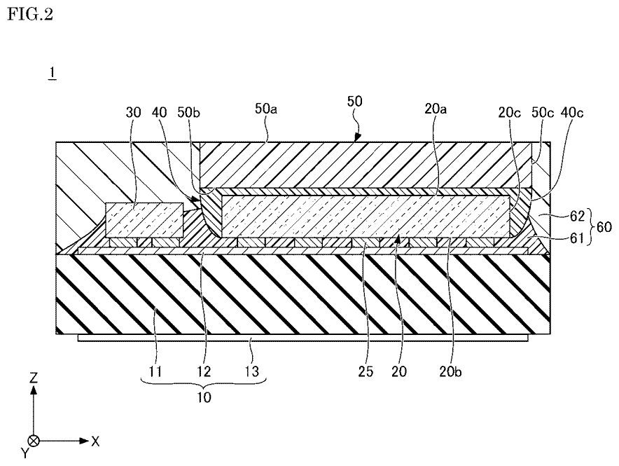

FIG. 1 is a schematic perspective view illustrating a light-emitting device according to the present embodiment. FIG. 2 is a cross-sectional view taken along line II-II in FIG. 1. FIG. 2 illustrates a cross section of a light-emitting device 1 taken along a plane perpendicular to an upper surface 20a of a light-emitting element 20. The same applies to the following cross-sectional views.

In each of the drawings, an X-axis, a Y-axis, and a Z-axis orthogonal to one another are illustrated for reference as necessary. A direction parallel to the X-axis is referred to as a first direction X, a direction parallel to the Y-axis is referred to as a second direction Y, and a direction parallel to the Z-axis is referred to as a third direction Z. In addition, in the first direction X, a direction in which an arrow is directed is referred to as a +X direction, and a direction opposite to the +X direction is referred to as a −X direction. In the second direction Y, a direction in which an arrow is directed is referred to as a +Y direction, and a direction opposite to the +Y direction is referred to as a −Y direction. In the third direction Z, a direction in which an arrow is directed is referred to as a +Z direction, and a direction opposite to the +Z direction is referred to as a −Z direction. However, these directions do not limit the orientation of the light-emitting device during use, and any orientation of the light-emitting device during use may be employed. Furthermore, a view in which a target object is viewed from the +Z direction toward the −Z direction is referred to as a top view.

As illustrated in FIGS. 1 and 2, the light-emitting device 1 includes a wiring substrate 10, the light-emitting element 20, a protective element 30, a bonding member 40, a light-transmissive member 50, and a covering member 60. The light-emitting device 1 may not include the protective element 30 or the wiring substrate 10.

In the light-emitting device 1, the light-emitting element 20 is disposed on the wiring substrate 10. Furthermore, in the light-emitting device 1, the protective element 30 may be disposed on the wiring substrate 10. The light-emitting element 20 has the upper surface 20a, a plurality of lateral surfaces 20c continuous with the upper surface 20a, and a lower surface 20b on an opposite side to the upper surface 20a. The plurality of lateral surfaces 20c are continuous with the upper surface 20a and the lower surface 20b. In other words, each of the plurality of lateral surfaces 20c has an outer edge continuous with an outer edge of the upper surface 20a and an outer edge of the lower surface 20b. The light-emitting element 20 can emit light from the upper surface 20a, the lower surface 20b, and the lateral surfaces 20c.

The light-emitting element 20 has a substantially rectangular upper surface 20a. For example, the light-emitting element 20 has a substantially rectangular parallelepiped or substantially cubic external shape. In this case, the upper surface 20a and the lower surface 20b of the light-emitting element 20 are substantially rectangular, and the light-emitting element 20 has four substantially rectangular lateral surfaces 20c. For example, two sides of the upper surface 20a of the light-emitting element 20 are parallel to the first direction X, and the other two sides are parallel to the second direction Y The normal line of the upper surface 20a is parallel to the third direction Z. The upper surface 20a of the light-emitting element 20 may have a polygonal shape such as a triangular shape or a hexagonal shape. Further, the light-emitting element 20 may have an external shape of a columnar body or a frustum body having a polygonal shape.

The bonding member 40 is disposed between the upper surface 20a of the light-emitting element 20 and the lower surface 50b of the light-transmissive member 50. The bonding member 40 covers the upper surface 20a and at least a portion of the lateral surfaces 20c of the light-emitting element 20. To be specific, the bonding member 40 covers the entire upper surface 20a of the light-emitting element 20, and at least a portion of the upper end side (that is, the outer edge side continuous with the upper surface 20a) of each of the lateral surfaces 20c. The bonding member 40 includes a lateral surface 40c continuous with the lateral surface 20c of the light-emitting element 20 and a lower surface 50b of the light-transmissive member 50. The bonding member 40 preferably covers a larger area of each of the lateral surfaces 20c of the light-emitting element 20, and more preferably covers each of the lateral surfaces 20c substantially in its entirety. That is, the lateral surface 40c of the bonding member 40 is preferably in contact with each of the lateral surfaces 20c of the light-emitting element 20 at a position close to the lower end side of the lateral surface 20c (i.e., the side continuous with the lower surface 20b), and more preferably in contact with the lower end of each of the lateral surfaces 20c. To be specific, the bonding member 40 covers preferably 75% or more and 100% or less, more preferably 90% or more and 100% or less of the region of each of the lateral surfaces 20c of the light-emitting element 20 in the height direction from the upper end side.

The bonding member 40 has transmissivity with respect to light emitted from the light-emitting element 20. The light emitted from the light-emitting element 20 is incident on the light-transmissive member 50 through the bonding member 40, and is emitted to the outside through the light-transmissive member 50. The bonding member 40 contains light scattering particles as an additive. The bonding member 40 contains the light scattering particles, and covers larger areas of the lateral surfaces 20c of the light-emitting element 20, so that a larger amount of light emitted from the lateral surfaces 20c of the light-emitting element 20 can be guided toward the lower surface 50b of the light-transmissive member 50.

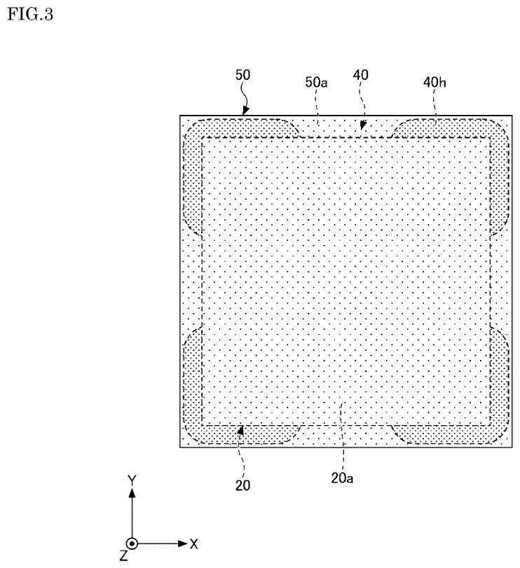

FIG. 3 is a schematic view of a light-emitting element, a bonding member, and a light-transmissive member in the light-emitting device 1 as viewed from an upper surface side of the light-transmissive member. In the bonding member 40 illustrated in FIG. 3, a region where the concentration of the light scattering particles is relatively high is indicated by a thick dot pattern, and a region where the concentration of the light scattering particles is relatively low is indicated by a thin dot pattern. In other drawings, the level of the concentration of the light scattering particles in the bonding member 40 may be indicated by similar dot patterns.

As illustrated in FIG. 3, the bonding member 40 at a position not overlapping the light-emitting element 20 in a top view (that is, outside the light-emitting element 20) includes a region 40h having a higher concentration of light scattering particles than the bonding member 40 at a position overlapping the light-emitting element 20 in a top view. That is, a ratio of the weight of the light scattering particles to the weight of the bonding member 40 at the position not overlapping the light-emitting element 20 in a top view is higher than a ratio of the weight of the light scattering particles to the weight of the bonding member 40 at the position overlapping the light-emitting element 20 in a top view. The region 40h of the bonding member 40 having a higher concentration of the light scattering particles can include a portion disposed so as to be in contact with the outer edge of the upper surface 20a of the light-emitting element 20 in a top view. FIG. 3 illustrates an example in which the region 40h is in contact with the outer edge of the upper surface 20a of the light-emitting element 20 and is disposed along the outside of the four corners in a top view, but the position at which the region 40h is disposed is not limited thereto. It is preferable that there is no clear interface between the region 40h and its peripheral region.

As illustrated in FIGS. 1 and 2, the light-transmissive member 50 is disposed on the upper surface 20a of the light-emitting element 20 via the bonding member 40. The light-transmissive member 50 has an upper surface 50a, a lower surface 50b on an opposite side to the upper surface 50a, and lateral surfaces 50c between the upper surface 50a and the lower surface 50b. The upper surface 50a of the light-transmissive member 50 serves as the main light-emitting surface of the light-emitting device 1 and constitutes the upper surface of the light-emitting device 1. The light-transmissive member 50 is disposed on the light-emitting element 20 via the bonding member 40 disposed on the upper surface 20a of the light-emitting element 20 such that the lower surface 50b of the light-transmissive member 50 faces the upper surface 20a of the light-emitting element 20. The light-transmissive member 50 is disposed such that the lower surface 50b of the light-transmissive member 50 is substantially parallel to the upper surface 20a of the light-emitting element 20. The shape of the lower surface 50b of the light-transmissive member is preferably similar to the shape of the upper surface 20a of the light-emitting element. For example, when the upper surface 20a of the light-emitting element has a rectangular shape, preferably the lower surface 50b of the light-transmissive member also has a rectangular shape.

The lower surface 50b of the light-transmissive member 50 is a flat surface. The upper surface 50a of the light-transmissive member 50 may be a flat surface parallel to the lower surface 50b, or a part or all of the upper surface 50a may have a surface that is not parallel to the lower surface 50b. The light-transmissive member 50 preferably has the lower surface 50b having a larger area than the upper surface 20a of the light-emitting element 20. The light-transmissive member 50 is preferably disposed such that the lower surface 50b of the light-transmissive member 50 encloses the light-emitting element 20 in a top view. In the light-emitting device 1, the bonding member 40 interposed between the lower surface 50b of the light-transmissive member 50 and the upper surface 20a of the light-emitting element 20 is preferably in contact with the entire lower surface 50b of the light-transmissive member 50. That is, in the light-emitting device 1, the bonding member 40 is preferably disposed so as to reach the entire outer edge including four corners of the lower surface 50b of the light-transmissive member 50 having a rectangular shape, and preferably, the entire lower surface 50b is covered with the bonding member 40.

For example, when there is a region exposed from the bonding member 40 at the corners of the lower surface 50b of the light-transmissive member 50 having the rectangular shape, the light emitted from the light-emitting element 20 is less likely to be incident on the region. Thus, the brightness decreases at the corners of the upper surface 50a of the light-transmissive member 50, and brightness unevenness may occur on the light-emitting surface of the light-emitting device 1 (that is, the upper surface of the light-transmissive member 50). On the other hand, in the light-emitting device 1, the bonding member 40 is in contact with the entire lower surface 50b of the light-transmissive member 50, and thus a larger amount of the light emitted from the light-emitting element 20 can be incident on the lower surface 50b of the light-transmissive member 50 through the bonding member 40. As a result, a decrease in brightness at the corners of the upper surface 50a of the light-transmissive member 50 can be reduced, and the light-emitting device 1 with less brightness unevenness can be realized.

The covering member 60 allows the upper surface 50a of the light-transmissive member 50 to be exposed, and covers the lateral surfaces 40c of the bonding member 40 and the lateral surfaces 50c of the light-transmissive member 50. The covering member 60 further covers an upper surface of the wiring substrate 10. In the case in which the light-emitting device 1 includes the protective element 30, the covering member 60 preferably covers an upper surface and lateral surfaces of the protective element 30. The covering member 60 may cover the lower surface 20b of the light-emitting element 20. In the case in which a portion of the lateral surfaces 20c of the light-emitting element 20 is exposed from the bonding member 40, the covering member 60 may directly cover the lateral surfaces 20c of the light-emitting element 20 exposed from the bonding member 40.

The covering member 60 preferably has a light shielding property, and specifically has a light reflecting property and/or a light absorbing property. In particular, the covering member 60 preferably has the light reflecting property in order to suitably reflect the light emitted from the light-emitting element 20.

With the covering member 60 covering the lateral surfaces 40c of the bonding member 40, light emitted from the lateral surfaces 20c of the light-emitting element 20 and transmitted through the bonding member 40 is reflected by the covering member 60. The covering member 60 may cover the lower surface 20b of the light-emitting element 20. In this case, light emitted from the lower surface 20b of the light-emitting element 20 and traveling downward can be reflected by the covering member 60. Thus, light extraction efficiency in the light-emitting device 1 can be improved.

The covering member 60 may be made up of a single member or a plurality of members. In the example illustrated in FIG. 2, the covering member 60 is made up of a plurality of portions including a first covering member 61 and a second covering member 62.

In the covering member 60, the first covering member 61 is disposed on the wiring substrate 10 side. The first covering member 61 covers, for example, the upper surface of the wiring substrate 10. The first covering member 61 contacts the bonding member 40. The first covering member 61 may cover the lower surface 20b of the light-emitting element 20. In the case in which the light-emitting device 1 includes the protective element 30, the first covering member 61 covers, for example, at least a portion of the lateral surfaces of the protective element 30. The first covering member 61 may cover the lower surface of the protective element 30.

In the covering member 60, the second covering member 62 is disposed on the first covering member 61, for example. The second covering member 62 allows the upper surface 50a of the light-transmissive member 50 to be exposed, covers the lateral surfaces 50c of the light-transmissive member 50 and the lateral surfaces 40c of the bonding member 40, and is in contact with the first covering member 61. In the case in which the light-emitting device 1 includes the protective element 30, the second covering member 62 covers, for example, the upper surface of the protective element 30. The second covering member 62 may cover a portion of the lateral surfaces of the protective element 30 exposed from the first covering member 61.

The lateral surface of the second covering member 62 constitutes the lateral surface of the light-emitting device 1 together with the lateral surface of the wiring substrate 10. The lateral surface of the second covering member 62 and the lateral surface of the wiring substrate 10 may be flush with each other, for example. The upper surface of the second covering member 62 and the upper surface 50a of the light-transmissive member 50 can be flush with each other, for example.

In the light-emitting device 1, when a current is supplied from an external power supply to the light-emitting element 20, the light-emitting element 20 emits light. Of the light emitted from the light-emitting element 20, the light traveling upward (i.e., toward the lower surface of the light-transmissive member) is extracted to the outside of the light-emitting device 1 through the bonding member 40 and the light-transmissive member 50. Of the light emitted from the light-emitting element 20, the light traveling downward is reflected by the covering member 60 and the wiring substrate 10, and extracted to the outside of the light-emitting device 1 through the light-emitting element 20, the bonding member 40, and the light-transmissive member 50. Of the light emitted from the light-emitting element 20, light traveling in the lateral direction is reflected at the interface between the lateral surface 20c of the bonding member 40 and the covering member 60 and extracted to the outside of the light-emitting device 1 through the bonding member 40 and the light-transmissive member 50.

Hereinafter, each element constituting the light-emitting device 1 according to the embodiment will be described in detail.

### Wiring Substrate 10

The wiring substrate 10 is a member on which the light-emitting element 20 is disposed. The wiring substrate 10 includes a wiring line for supplying electric power to the light-emitting element from the outside, and a base body 11 supporting the wiring line. The wiring substrate 10 includes, for example, an upper surface wiring line 12 disposed on an upper surface on which the light-emitting element 20 is disposed, and a lower surface wiring line 13 disposed on a lower surface on an opposite side to the upper surface. The base body 11 has, for example, a substantially rectangular parallelepiped shape or a substantially cubic shape. The base body 11 is preferably made of an insulating material that is less likely to transmit light emitted from the light-emitting element 20, external light, and the like. Examples of the material of the base body 11 include a single material selected from ceramics such as aluminum oxide, aluminum nitride, silicon nitride, and mullite, resins such as epoxy resin, silicone resin, modified epoxy resin, urethane resin, phenol resin, polyimide resin, BT resin, and polyphthalamide, semiconductors such as silicon, and metals such as copper and aluminum, and composite materials thereof. Among these, ceramic having excellent heat dissipation properties can be suitably used as the material of the base body 11.

The upper surface wiring line 12 includes a wiring line electrically connected to the light-emitting element 20 and a wiring line electrically connected to the protective element 30. The lower surface wiring line 13 includes an anode electrode and a cathode electrode having a region for ensuring electrical connection with an external power supply (that is, serving as electrodes of the light-emitting device 1). For the upper surface wiring line 12 and the lower surface wiring line 13, for example, a metal such as iron, copper, nickel, aluminum, gold, silver, platinum, titanium, tungsten, or palladium, or an alloy containing at least one of these metals can be used. Further, the wiring substrate 10 may include a relay wiring line for connecting the upper surface wiring line 12 and the lower surface wiring line 13 inside and/or on the lateral surface of the base body 11. Further, the wiring substrate 10 may include, on the lower surface side, a heat dissipation terminal electrically independent of the upper surface wiring line 12.

The wiring substrate 10 may not include the lower surface wiring line 13. In this case, an anode electrode and a cathode electrode electrically connected to an external power supply may be disposed on the upper surface or the lateral surface of the wiring substrate 10.

The wiring substrate 10 may include, on the upper surface, a recessed portion. In this case, the light-emitting device 1 may have a structure in which the light-emitting element 20 is disposed at the bottom of the recessed portion of the wiring substrate 10. The light-emitting device 1 may have a structure without the wiring substrate 10. For example, the light-emitting device 1 may have a structure in which an electrode of the light-emitting element 20 and/or a conductive member such as a plating layer disposed on the electrode of the light-emitting element 20 are provided as external connection electrodes of the light-emitting device 1 from the covering member 60 covering the lower surface 20b of the light-emitting elements 20.

In the wiring substrate 10, a lead (specifically, a metal thin plate) may be used as the wiring line. In this case, the wiring substrate 10 includes a lead as a wiring line, and a resin molded body as a base body to hold the lead. For the lead, the above-described metal, alloy, or the like is used, and processed into a predetermined shape by processing such as rolling, punching, extrusion, etching such as wet or dry etching, or a combination thereof.

### Light-Emitting Element 20

As the light-emitting element 20, a semiconductor light-emitting element such as a light-emitting diode (LED) chip or a semiconductor laser (LD) chip can be suitably used. Any shape, size, and the like can be selected for the light-emitting element 20. The light-emitting element 20 has, for example, positive and negative electrodes on the lower surface 20b. The light-emitting element 20 is disposed on the wiring substrate 10. The light-emitting element 20 is, for example, flip-chip mounted on the wiring substrate 10 via a conductive bonding member 25 with the lower surface 20b facing the wiring substrate 10. As the conductive bonding member 25, for example, a known member such as eutectic solder, conductive paste, or bump can be used.

The light-emitting element 20 includes, for example, a semiconductor structure and a support substrate supporting the semiconductor structure. The semiconductor structure includes an n-side semiconductor layer, a p-side semiconductor layer, and a light-emitting layer interposed between the n-side semiconductor layer and the p-side semiconductor layer. The light-emitting layer may have a single quantum well (SQW) structure, or may have a multi quantum well (MQW) structure including a plurality of well layers. The semiconductor structure includes a plurality of semiconductor layers each made of a nitride semiconductor. Examples of the nitride semiconductor include semiconductors having all compositions in which in a chemical formula of InₓAl_{y}Ga_{1-x-y}N (0≤x, 0≤y, and x+y≤1), composition ratios x and y are changed within respective ranges. The light emission peak wavelength of the light-emitting layer can be selected as appropriate according to the purpose. The light-emitting layer is configured, for example, so as to be able to emit visible light or ultraviolet light.

The light-emitting element 20 may have one semiconductor structure on one support substrate, or may have a plurality of semiconductor layered bodies on one support substrate. In addition, one semiconductor structure may have only one light-emitting layer, or may have a plurality of light-emitting layers. The semiconductor structure including the plurality of light-emitting layers may be a structure including the plurality of light-emitting layers between one n-side semiconductor layer and one p-side semiconductor layer, or may be a structure in which a layered structure including the n-side semiconductor layer, the light-emitting layer, and the p-side semiconductor layer in sequence is repeatedly formed multiple times.

The light-emitting element 20 includes an n-electrode connected to the n-side semiconductor layer and a p-electrode connected to the p-side semiconductor layer. The p-electrode and the n-electrode may be disposed on different surface sides of the semiconductor layered body, or may be disposed on the same surface side. Here, the electrodes including the p-electrode and the n-electrode are disposed on the same surface side of the semiconductor structure, the side on which the electrodes are disposed constitutes the lower surface 20b of the light-emitting element 20, and the surface of the support substrate on an opposite side to the surface on which the semiconductor structure is disposed constitutes the upper surface 20a of the light-emitting element 20. Examples of the support substrate include an insulating substrate of sapphire or spinel (MgAl₂O₄), and a nitride-based semiconductor substrate of gallium nitride. Preferably, the support substrate uses a material having transmissivity with respect to light emitted from the light-emitting layer in order to extract light emitted from the light-emitting layer through the support substrate. The light-emitting element 20 does not necessarily include the support substrate. In this case, the surface on an opposite side to the surface on which the electrodes of the semiconductor structure are disposed constitutes the upper surface 20a of the light-emitting element 20.

### Protective Element 30

The light-emitting device 1 can include other electronic components such as the protective element 30 in addition to the light-emitting element 20. The protective element 30 is, for example, a Zener diode. The light-emitting device 1 may not include the protective element 30.

### Bonding Member 40

The bonding member 40 is disposed between the light-emitting element 20 and the light-transmissive member 50, and bonds the light-emitting element 20 and the light-transmissive member 50. As described above, the bonding member 40 has transmissivity, and guides the light emitted from the light-emitting element 20 to the light-transmissive member 50. With the bonding member 40 covering the lateral surfaces 20c of the light-emitting element 20, light emitted from the lateral surfaces 20c of the light-emitting element 20 can be easily guided to the light-transmissive member 50, so that the light extraction efficiency of the light-emitting device 1 can be improved.

The bonding member 40 is disposed so as to cover the upper surface 20a and each of the lateral surfaces 20c of the light-emitting element 20. For example, a light-transmissive resin can be used as the bonding member 40. Examples of the light-transmissive resin include thermosetting resins such as an epoxy resin, a modified epoxy resin, a silicone resin, and a modified silicone resin. Among them, a silicone resin having high heat resistance is preferably used. When a silicone resin is used for the bonding member 40, a dimethyl silicone resin or a phenyl methyl silicone resin may be used. The phenyl methyl silicone resin has a higher refractive index than the dimethyl silicone resin, and thus can improve the light extraction efficiency of the light-emitting device 1. In addition, as the bonding member 40, a silicon alcoholate such as polysilazane having more excellent heat resistance may be used.

Examples of the light scattering particles contained in the bonding member 40 include silicon oxide, titanium oxide, aluminum oxide, and barium titanate. One of these types of light scattering particles can be used alone, or a combination of two or more of these types can be used. Since the bonding member 40 contains the light scattering particles, it is possible to reduce the light emission unevenness of light emitted from the light-emitting layer of the light-emitting element 20, and to make the distribution of the light incident on the lower surface 50b of the light-transmissive member 50 nearly uniform. When a silicone resin (having a refractive index in a range from about 1.41 to about 1.55 at 25° C.) is used for the bonding member 40, silicon oxide having a refractive index close to that of the silicone resin is preferably used as the light scattering particles. Thus, it is possible to reduce a decrease in the light transmittance of the bonding member 40 containing the light scattering particles. A particle diameter of the light scattering particle is in a range from 1 nm to 10 μm. In particular, nanoparticles such as nanosilica are preferably used as the light scattering particles. By using the nanoparticles, a viscosity of an uncured bonding member 40 can be adjusted. Thus, the uncured bonding member 40 is easily disposed at a desired position in the manufacturing process of the light-emitting device 1. The nanoparticle refers to a particle having a particle diameter in a range from 1 nm to 100 nm. The term “particle diameter” as used herein refers to the average particle diameter, and the value of the average particle diameter is determined by the air permeability method or Fisher-SubSieve-Sizers No. (F.S. S. S. No.) (value indicated by so-called D bar (bar above D)). Examples of the shape of the light scattering particle include a spherical shape, an irregularly crushed shape, a needle shape, a columnar shape, a plate shape (including scaly shape), a fibrous shape, and a dendritic shape (the same applies to a light reflective material and/or a phosphor described later). The light scattering particles may be hollow or porous.

### Light-Transmissive Member 50

The light-transmissive member 50 is disposed on the light-emitting element 20, and transmits the light emitted from the light-emitting element 20 to the outside. The light-transmissive member 50 transmits 60% or more, preferably 70% or more, of light from the light-emitting element 20 and/or wavelength-converted light of the light from the light-emitting element 20 (e.g., light having wavelengths in the range of 320 nm to 850 nm). The light-transmissive member 50 may be made of, for example, an inorganic material such as glass, ceramic, or sapphire, or an organic material such as a resin or a hybrid resin containing one or more of a silicone resin, a modified silicone resin, an epoxy resin, a modified epoxy resin, an acrylic resin, a phenol resin, and a fluororesin. The light-transmissive member 50 may contain a phosphor that can convert the wavelength of at least a portion of incident light. Examples of the light-transmissive member 50 containing the phosphor include a sintered body of phosphor and a material in which phosphor powder is contained in the above-described material. The light-transmissive member 50 may be a member in which a phosphor layer such as a resin layer containing a phosphor or a glass layer containing a phosphor is disposed on a surface of a light-transmissive plate that is a molded body made of resin, glass, ceramic, or the like. The light-transmissive member 50 may contain a filler such as light scattering particles depending on the purpose. In the case in which the light-transmissive member 50 contains the filler such as the light scattering particles, the light-transmissive member 50 may be made of a resin, glass, ceramic, or other inorganic material containing a filler, or may include a light scattering layer, such as a resin layer containing a filler such as light scattering particles or a glass layer containing a filler, disposed on a surface of a light-transmissive plate that is a molded body of a resin, glass, ceramic, or the like.

As the phosphor, an yttrium aluminum garnet-based phosphor (for example, (Y,Gd)₃(Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), an oxynitride-based phosphor such as a β-SiAlON-based phosphor (for example, (Si,Al)₃(O,N)₄:Eu) or an α-SiAlON-based phosphor (for example, Ca(Si,Al)₁₂(O,N)₁₆:Eu), a nitride-based phosphor such as an LSN-based phosphor (for example, (La,Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), or an SCASN-based phosphor (for example, (Sr,Ca)AlSiN₃:Eu), a fluoride-based phosphor such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), or an MGF-based phosphor (for example, 3.5MgO·0.5MgF₂·GeO₂:Mn), a quantum dot having a perovskite structure (for example, (Cs,FA,MA)(Pb,Sn)(F,Cl,Br,I)₃, where FA and MA represent formamidinium and methylammonium, respectively), a group II-VI quantum dot (for example, CdSe), a group III-V quantum dot (for example, InP), a quantum dot having a chalcopyrite structure (for example, (Ag,Cu)(In,Ga)(S,Se)₂), or the like can be used.

As the light scattering particles, the same light scattering particles as used in the bonding member 40 can be used.

Further, when a resin is employed for a binder of a phosphor layer and a light scattering layer, examples of the resin include thermosetting resins such as an epoxy resin, a modified epoxy resin, a silicone resin, and a modified silicone resin.

Furthermore, in order to improve light extraction, the upper surface and/or the lower surface of the light-transmissive member 50 may have an optical thin film such as an anti-reflective film, or the lateral surfaces of the light-transmissive member 50 may have an optical film such as a reflective film.

### Covering Member 60

The covering member 60 is a member that allows the upper surface 50a of the light-transmissive member 50 to be exposed, and covers the lateral surfaces 40c of the bonding member 40 and the lateral surfaces 50c of the light-transmissive member 50. The covering member 60 preferably has, for example, a reflectance of 60% or more, and more preferably has a reflectance of 70% or more, 80% or more, or 90% or more, relative to the light emitted from the light-emitting element 20.

Preferably, the covering member 60 is formed using an insulating material. The covering member 60 is, for example, a member containing particles of a light-reflective substance and a base material. Examples of the base material to be used for the covering member 60 include a resin or a hybrid resin containing one or more of a silicone resin, a modified silicone resin, an epoxy resin, a modified epoxy resin, a urea resin, an acrylic resin, a phenol resin, a bismaleimide triazine resin, and a polyphthalamide resin. Among these, it is particularly preferable to use a silicone resin which is excellent in light resistance, heat resistance, and electrical insulation properties and has flexibility. The base material may be made of an inorganic material such as an alkali metal silicate. Examples of the light-reflective substance include titanium oxide, silicon oxide, aluminum oxide, zirconium oxide, magnesium oxide, potassium titanate, barium titanate, zinc oxide, silicon nitride, aluminum nitride, boron nitride, calcium carbonate, calcium hydroxide, calcium silicate, and combinations thereof. Among these, from the viewpoint of light reflection, titanium oxide having a relatively high refractive index is preferably used.

As described above, the covering member 60 may be made up of the first covering member 61 and the second covering member 62. In this case, each of the first covering member 61 and the second covering member 62 can be made using a material selected from the materials described above as examples of the material of the covering member 60. The covering member 60 is made up of the first covering member 61 and the second covering member 62, so that for example, the second covering member 62 constituting the outer surfaces of the light-emitting device 1 can be made of a material having a high mechanical strength, while the first covering member 61 covering the lower surface 20b of the light-emitting element 20 can be made of a material having a low elastic modulus and/or a low linear expansion coefficient, to make it possible to relax a stress due to resin expansion.

### Method of Manufacturing Light-Emitting Device According to Embodiment

A method of manufacturing a light-emitting device according to an embodiment includes a step of preparing a light-emitting element, a step of preparing a light-transmissive member having a lower surface having a larger area than an upper surface of the light-emitting element, a step of disposing an uncured first bonding member on at least a portion of an outer peripheral region of the upper surface of the light-emitting element, a step of disposing an uncured second bonding member having a lower viscosity than the uncured first bonding member on the upper surface of the light-emitting element exposed from the first bonding member, a step of pressing the first bonding member and the second bonding member by the lower surface of the light-transmissive member to spread the first bonding member and/or the second bonding member in an outer peripheral region of the lower surface of the light-transmissive member, and a step of curing the first bonding member and the second bonding member.

Hereinafter, each manufacturing step of the method of manufacturing the light-emitting device according to the embodiment will be described with reference to the drawings.

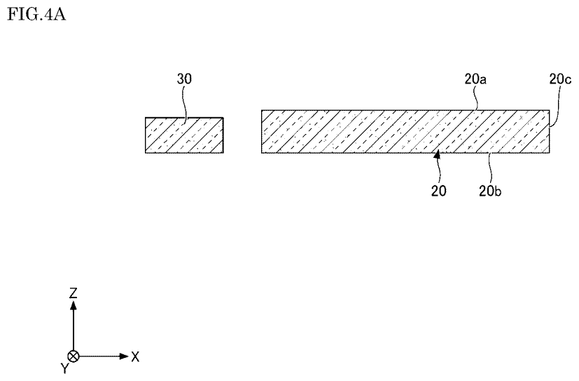

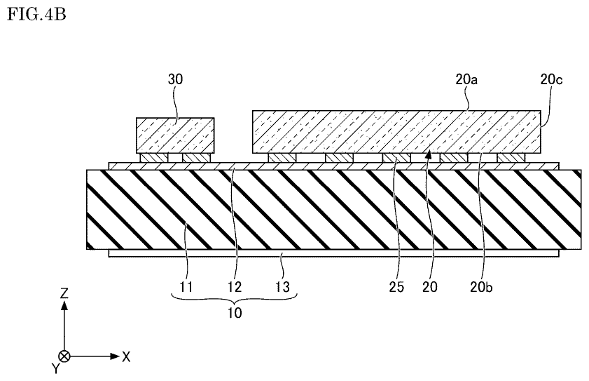

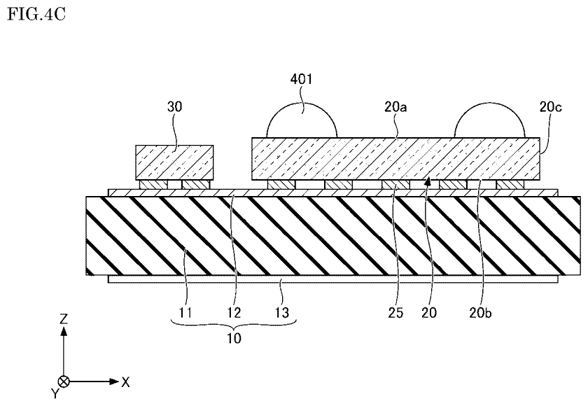

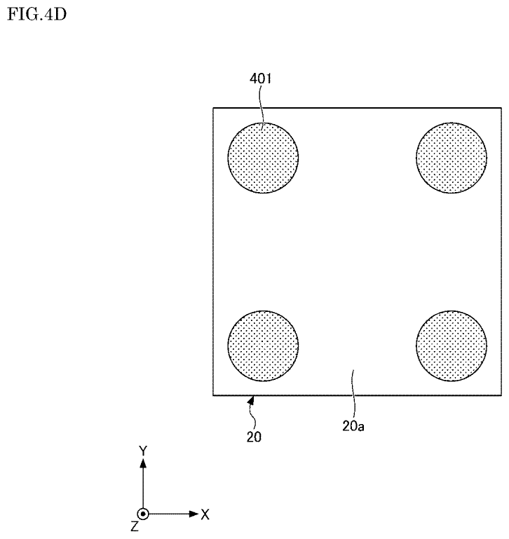

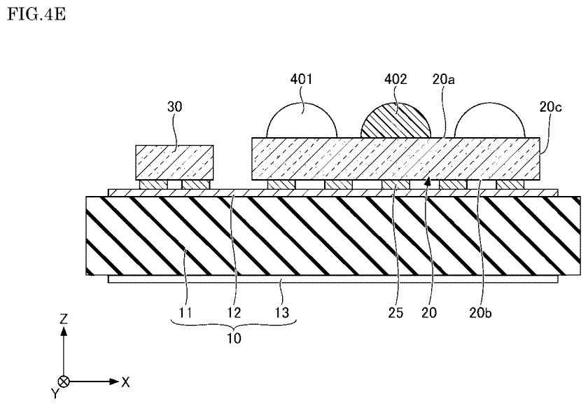

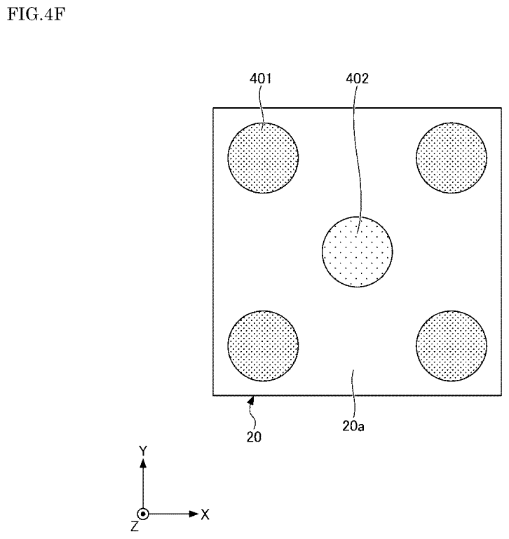

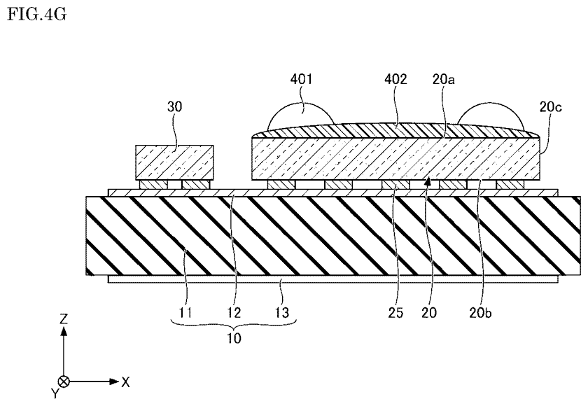

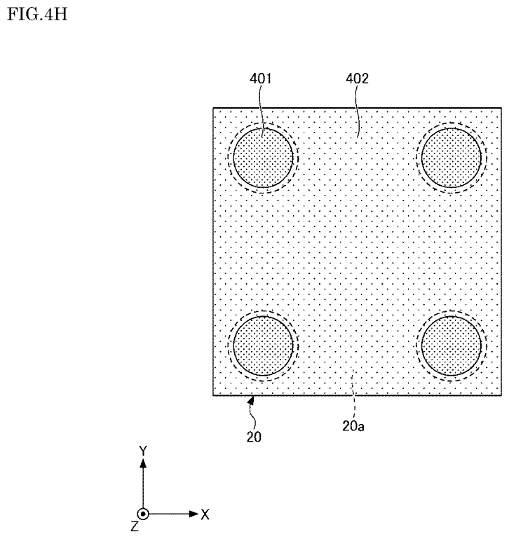

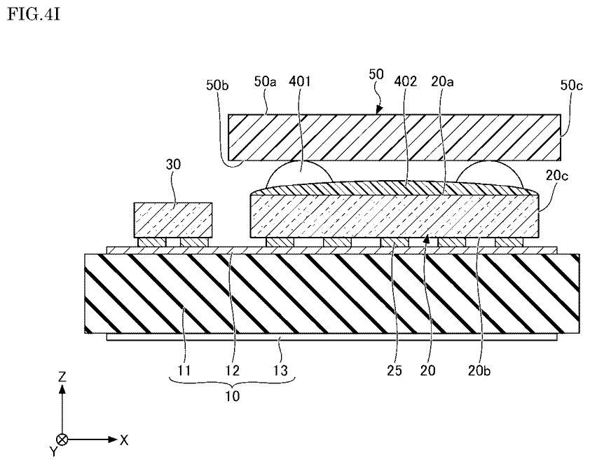

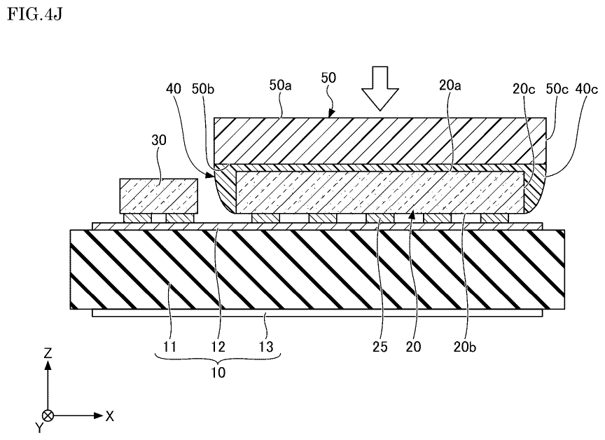

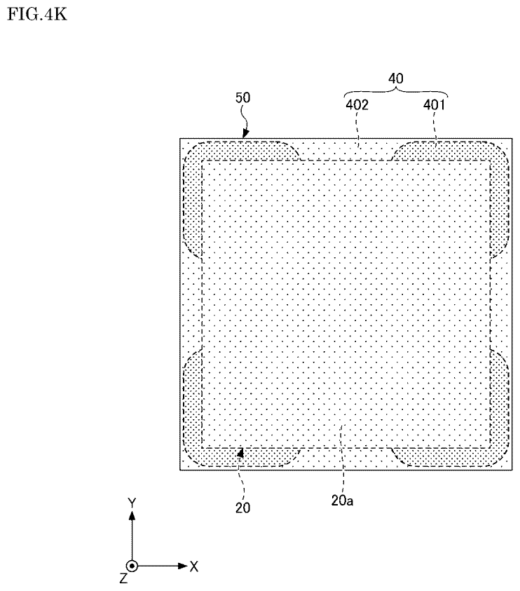

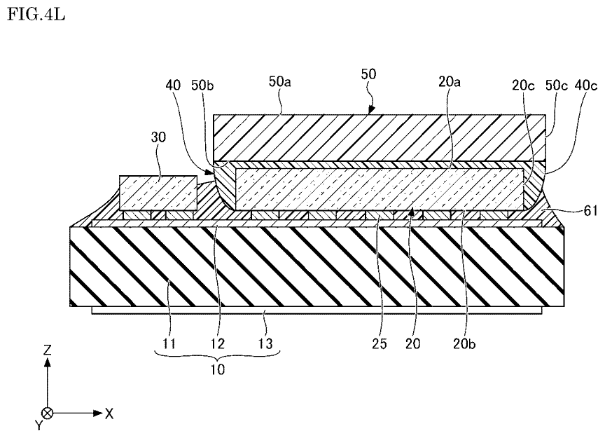

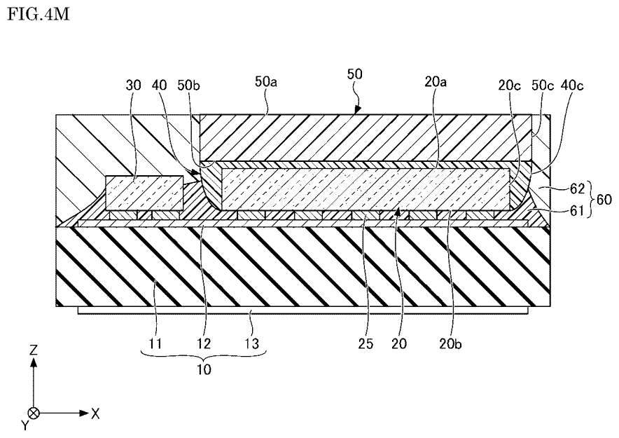

FIGS. 4A to 4M are schematic views, each illustrating a manufacturing process of the light-emitting device according to the present embodiment. Specifically, FIGS. 4A, 4B, 4C, 4E, 4G, 4I, 4J, 4L, and 4M are schematic cross-sectional views, each illustrating the manufacturing process of the light-emitting device according to the present embodiment. Each of FIGS. 4D, 4F, and 4H is a schematic view of the light-emitting element, the first bonding members, and the second bonding member as viewed from the upper surface side of the light-emitting element. FIG. 4K is a schematic view of the light-emitting element, the first bonding members, the second bonding member, and the light-transmissive member as viewed from the upper surface side of the light-transmissive member.

### Step of Preparing Light-Emitting Element

First, as illustrated in FIG. 4A, the light-emitting element 20 having the upper surface 20a, the lower surface 20b, and the plurality of lateral surfaces 20c continuous with the upper surface 20a and the lower surface 20b is prepared. Further, the protective element 30 is prepared as necessary. The light-emitting element 20 can be prepared through some or all of a plurality of steps such as a step of forming a semiconductor layered body and a step of forming an electrode. In the description of the manufacturing method, the expression “preparing” a member is not limited to manufacturing the member, and includes acquiring the member such as purchasing the member and receiving the member.

### Step of Preparing Wiring Substrate and Step of Disposing Light-Emitting Element on Wiring Substrate

Next, as illustrated in FIG. 4B, the wiring substrate 10 is prepared, and the light-emitting element 20 is disposed on the wiring substrate 10. Specifically, first, the wiring substrate 10 including the base body 11, the upper surface wiring line 12 provided on the upper surface of the base body 11, and the lower surface wiring line 13 provided on the lower surface of the base body 11 is prepared. Then, the light-emitting element 20 is disposed on the upper surface side of the wiring substrate 10. Here, the protective element 30 is disposed together with the light-emitting element 20. The light-emitting element 20 and the protective element 30 are flip-chip mounted on the wiring substrate 10 via the conductive bonding member 25 disposed on the wiring substrate 10 in advance. In the disposing step, the conductive bonding member 25 may be disposed on the light-emitting element 20 side in advance. Examples of the conductive bonding member 25 disposed on the light-emitting element 20 side include a conductive member such as a plating layer disposed on the electrode of the light-emitting element 20. In the disposing step, the conductive bonding member 25 may be disposed on both the light-emitting element 20 side and the wiring substrate 10 side.

### Step of Disposing First Bonding Member

Next, as illustrated in FIGS. 4C and 4D, uncured first bonding members 401 are disposed on at least a portion of an outer peripheral region of the upper surface 20a of the light-emitting element 20. The uncured first bonding members 401 are cured together with a second bonding member described later to constitute the bonding member 40 that bonds the light-transmissive member 50 and the light-emitting element 20 to each other in the light-emitting device 1. For the first bonding member 401, the material described above as the material for the bonding member 40 can be used. The viscosity of the uncured first bonding member 401 can be in a range, for example, from 30 Pa·s to 120 Pa·s. The outer peripheral region of the upper surface 20a is a region having a constant width from the outer edge of the upper surface 20a. The constant width may be, for example, about one third of the length of one side of the upper surface 20a.

Here, as an example, a case will be described in which the upper surface 20a of the light-emitting element 20 has a rectangular shape and the uncured first bonding members 401 are disposed at the four corners of the upper surface 20a of the light-emitting element 20 so as to be spaced apart from each other.

First, a nozzle is disposed above one corner of the upper surface 20a of the light-emitting element 20, and the uncured first bonding member 401 is discharged from the nozzle. Then, after a predetermined amount of the first bonding member 401 is discharged, the discharge is stopped, the nozzle is moved to above the other corner of the outer peripheral region of the upper surface 20a of the light-emitting element 20, and the uncured first bonding member 401 is discharged from the nozzle. After the above operation is repeated to discharge the uncured first bonding member 401 to all the four corners of the rectangle, the nozzle is moved from above the light-emitting element 20. The uncured first bonding members 401 may be disposed at the four corners, using a multi-nozzle that can provide simultaneous multiple-point discharges by a single discharge operation to simultaneously apply the uncured first bonding members 401 to the plurality of corners.

The uncured first bonding members 401 disposed on the upper surface of the light-emitting element 20 may be spaced apart from the outer edge of the upper surface 20a, or may be in contact with the outer edge of the upper surface 20a. On the upper surface of the light-emitting element 20, each of the uncured first bonding members 401 has a hemispherical shape with a circular shape in a top view and a semicircular shape in a side view due to a surface tension as illustrated in FIGS. 4C and 4D. The term “uncured” refers to a state before the curing reaction proceeds, that is, a state before an operation for causing the curing reaction to proceed is performed. Examples of the operation for causing the curing reaction to proceed include heating and light irradiation. Although the curing reaction may slightly proceed before the operation for causing the curing reaction to proceed, the uncured state also includes such a state.

The uncured first bonding member 401 may be disposed in a frame shape in the outer peripheral region of the upper surface 20a of the light-emitting element 20. When the uncured first bonding member 401 is disposed in the frame shape, the nozzle may be moved above the outer peripheral region of the upper surface 20a of the light-emitting element 20 while discharging the uncured first bonding member 401 from the nozzle.

### Step of Disposing Second Bonding Member

Next, as illustrated in FIGS. 4E and 4F, an uncured second bonding member 402 having a lower viscosity than the uncured first bonding members 401 is disposed on a portion of the upper surface 20a of the light-emitting element 20 that is exposed from the first bonding members 401. For the second bonding member 402, the material described above as the material for the bonding member 40 can be used. The same resin material is preferably used as a base material for the first bonding member 401 and the second bonding member 402. The viscosity of the uncured second bonding member 402 can be in a range, for example, from 0.1 Pa·s to 15 Pa·s.

Here, as an example, a case will be described in which the uncured second bonding member 402 is disposed in a central region located inside the outer peripheral region of the upper surface 20a of the light-emitting element 20.

First, the nozzle is disposed above the central region of the upper surface 20a of the light-emitting element 20, and the uncured second bonding member 402 is discharged from the nozzle. Then, after a predetermined amount of the second bonding member 402 is discharged, the discharge is stopped, and the nozzle is moved from above the light-emitting element 20.

The uncured first bonding member 401 has a high viscosity, and thus, in the steps illustrated in FIGS. 4E and 4F, maintains substantially the same shape as that in the steps illustrated in FIGS. 4C and 4D. On the other hand, since the uncured second bonding member 402 has a low viscosity, it spreads from the discharge position to the periphery and reaches the four first bonding members 401. The second bonding member 402 having reached each of the first bonding members 401 further spreads along the first bonding members 401, and finally spreads over the entire upper surface 20a as illustrated in FIGS. 4G and 4H. The second bonding member 402 may creep up a skirt portion of the first bonding members 401, or may creep up the entire surface of the first bonding members 401.

When the uncured second bonding member 402 is discharged in a state in which the uncured first bonding members 401 are not disposed, the uncured second bonding member 402 spreads concentrically while maintaining an area as small as possible due to a surface tension, and thus is unlikely to reach the corners of the rectangle of the upper surface 20a of the light-emitting element 20. On the other hand, when the uncured second bonding member 402 is disposed in a state in which the uncured first bonding members 401 are disposed in the outer peripheral region of the upper surface of the light-emitting element 20, the uncured second bonding member 402 comes into contact with the first bonding members 401 and spreads over the upper surface 20a along the first bonding members 401 using capillarity starting from the contact portion with the first bonding members 401, and thus easily reaches the corners of the upper surface 20a.

In the step of disposing the second bonding member 402, a volume of the uncured second bonding member 402 disposed on the light-emitting element 20 is preferably larger than a volume of the uncured first bonding members 401 disposed on the light-emitting element 20 in the step of disposing the first bonding members 401. As the viscosity is lower, the light transmittance when the uncured first bonding members 401 and the uncured second bonding member 402 are cured is higher. The volume of the uncured second bonding member 402 having the low viscosity is larger than the volume of the uncured first bonding member 401 having the high viscosity, so that in the cured bonding member 40, a ratio occupied by the region where the uncured second bonding member 402 is cured becomes larger than a ratio occupied by the region where the uncured first bonding members 401 are cured, and thus the light transmittance can be increased.

When the viscosity of the uncured second bonding member 402 exceeds 15 Pa·s, a surface tension acts to make it difficult for the second bonding member 402 to spread. Thus, the viscosity of the uncured second bonding member 402 is preferably 15 Pa·s or less.

The viscosities of the uncured first bonding member 401 and the uncured second bonding member 402 can be adjusted, for example, by the physical properties of the base material to be selected, such as a resin, or by adding a filler for adjusting the viscosity (for example, nanoparticles such as the above-described light scattering particles) to the base material.

In the present embodiment, the uncured first bonding member 401 and the uncured second bonding member 402 both contain the resin material as the base material, and contain the light scattering particles. In this case, the viscosities of the uncured first bonding member 401 and the uncured second bonding member 402 can be adjusted by the amount of the light scattering particles to be contained. Specifically, as the concentration of the light scattering particles in the uncured bonding member is higher, the viscosity is higher. Further, even at the same concentration, as the particle diameter is smaller, the viscosity can be increased.

### Step of Preparing Light-Transmissive Member

Next, as illustrated in FIG. 4I, the light-transmissive member 50 having the lower surface 50b having a larger area than the upper surface 20a of the light-emitting element 20 is prepared. Next, the light-transmissive member 50 is disposed on the upper surface 20a of the light-emitting element 20 via the uncured first bonding members 401. The lower surface 50b of the light-transmissive member 50 is in contact with the uncured first bonding members 401. The uncured second bonding member 402 may be or may not be in contact with the lower surface 50b of the light-transmissive member 50.

The uncured first bonding member 401 has the high viscosity, and thus, in the step illustrated in FIG. 4I, maintains substantially the same shape as that in the steps illustrated in FIGS. 4G and 4H. Thus, the light-transmissive member 50 is easily held at the disposed position by a surface tension of the first bonding members 401, and is less likely to move in the first direction X or the second direction Y or rotate on the XY plane. That is, the light-transmissive member 50 is disposed on the first bonding members 401 each having the high viscosity, so that it is possible to reduce a positional deviation of the light-transmissive member 50 with respect to the upper surface 20a of the light-emitting element 20.

When the viscosity of the uncured first bonding member 401 is lower than 25 Pa·s, the surface tension decreases and the light-transmissive member 50 easily rotates on the XY plane. Thus, the viscosity of the uncured first bonding member 401 is preferably 30 Pa·s or more. On the other hand, when the viscosity of the uncured first bonding member 401 exceeds 120 Pa·s, the uncured first bonding member 401 is less likely to be deformed when pressed by the light-transmissive member 50. Thus, the viscosity of the uncured first bonding member 401 is preferably 120 Pa·s or less.

As described above, as the viscosity of the uncured first bonding member 401 is lower, the light transmittance when the uncured first bonding member 401 is cured is higher. Thus, when the light transmittance is also taken into consideration, the viscosity of the uncured first bonding member 401 is more preferably in a range from 30 Pa s to 70 Pa s, and further preferably in a range from 30 Pa·s to 50 Pa·s.

Step of Spreading First Bonding Member and/or Second Bonding Member, and Step of Curing Thereof

Next, the first bonding members 401 and the second bonding member 402 illustrated in FIG. 4I are pressed by the lower surface 50b of the light-transmissive member 50 in an arrow direction to spread the first bonding members 401 and/or the second bonding member 402 in the outer peripheral region of the lower surface 50b of the light-transmissive member 50 as illustrated in FIG. 4J. Here, the bonding member in which the first bonding member 401 and the second bonding member 402 are mixed is indicated by the reference character 40. It is preferable that a clear interface does not occur between the cured first bonding members 401 and the cured second bonding member 402. Here, a silicone resin is used as the base material of each of the first bonding members 401 and the second bonding member 402, and the first bonding members 401 and the second bonding member 402 are cured while being brought into contact with each other in an uncured state. Thus, the bonding member 40 can be obtained in which the first bonding members 401 and the second bonding member 402 are integrated (that is, there is no interface between the first bonding members 401 and the second bonding member 402).

When the first bonding members 401 are pressed by the lower surface 50b of the light-transmissive member 50, the first bonding members 401 start moving between the lower surface 50b of the light-transmissive member 50 and the upper surface 20a of the light-emitting element 20. Thereafter, when the lower surface 50b of the light-transmissive member 50 comes into contact with the second bonding member 402 to press the second bonding member 402, the second bonding member 402 located between the lower surface 50b of the light-transmissive member 50 and the upper surface 20a of the light-emitting element 20 spreads outward. Thus, for example, as illustrated in FIG. 4K, the second bonding member 402 is disposed with a substantially constant thickness in the entire region interposed between the upper surface 20a of the light-emitting element 20 and the lower surface 50b of the light-transmissive member 50.

The second bonding member 402 spreads between the lower surface 50b of the light-transmissive member 50 and the upper surface 20a of the light-emitting element 20, so as to push out the first bonding members 401 to the outside of the upper surface 20a of the light-emitting element 20. Thus, for example, as illustrated in FIG. 4K, the first bonding members 401 are disposed so as to be in contact with the outer edge of the upper surface 20a of the light-emitting element 20 at the four corners of the upper surface 20a of the light-emitting element 20 in a top view. In addition, the first bonding members 401 and/or the second bonding member 402 partially or entirely cover the lateral surfaces 20c of the light-emitting element 20. A portion of the first bonding members 401 may remain in a region interposed between the upper surface 20a of the light-emitting element 20 and the lower surface 50b of the light-transmissive member 50 (that is, a region where the light-emitting element 20 and the light-transmissive member 50 overlap each other in a plan view).

In addition, the first bonding members 401 and the second bonding member 402 are not pressed by the lower surface 50b of the light-transmissive member 50 in a region not interposed between the upper surface 20a of the light-emitting element 20 and the lower surface 50b of the light-transmissive member 50. Thus, the first bonding members 401 each having the high viscosity are unlikely to reach the outer peripheral portion of the lower surface 50b of the light-transmissive member 50, including the corners of the lower surface 50b. On the other hand, the second bonding member 402 having the low viscosity is likely to spread along the first bonding members 401 even in a region not interposed between the upper surface 20a of the light-emitting element 20 and the lower surface 50b of the light-transmissive member 50. Thus, as illustrated in FIG. 4K, the outer peripheral portion of the lower surface 50b of the light-transmissive member 50, including the corners of the lower surface 50b, is likely to be in contact with the second bonding member 402.

Thereafter, the first bonding members 401 and the second bonding member 402 are cured. The first bonding members 401 and the second bonding member 402 are cured simultaneously, so that the bonding member 40 in which the first bonding members 401 and the second bonding member 402 are integrated is formed, and the light-transmissive member 50 and the light-emitting element 20 are bonded to each other via the bonding member 40. The curing can be performed by a known method such as heating in an oven.

The uncured first bonding members 401 and the uncured second bonding member 402 are cured simultaneously, so that it is possible to form the bonding member 40 having no interface. Thus, the mechanical strength of the bonding member 40 can be improved. In addition, the light emitted from the light-emitting element 20 can be efficiently guided to the light-transmissive member 50.

In the light-emitting device 1, the bonding member 40 is preferably spaced apart from the wiring substrate 10. Separating the bonding member 40 from the wiring substrate 10 makes it possible to reduce reflection of light from the light-emitting element 20 in an unintended direction due to the bonding member 40 having an irregular shape. Thus, light extraction efficiency in the light-emitting device 1 can be improved.

### Step of Disposing First Covering Member

Next, as illustrated in FIG. 4L, the first covering member 61 is disposed on the wiring substrate 10. The first covering member 61 is disposed to cover at least a portion of the bonding member 40. Specifically, first, an uncured first covering member 61 is disposed on the wiring substrate 10. The uncured first covering member 61 can be disposed on the wiring substrate 10 by, for example, potting or spraying. The first covering member 61 covers, for example, the lower surface 20b of the light-emitting element 20, at least a portion of the lateral surfaces 40c of the bonding member 40, the lower surface of the protective element 30, and at least a portion of the lateral surfaces of the protective element 30. Thereafter, the uncured first covering member 61 is cured.

### Step of Disposing Second Covering Member

Next, as illustrated in FIG. 4M, the second covering member 62 is disposed to allow the upper surface 50a of the light-transmissive member 50 to be exposed, and cover the lateral surfaces 50c of the light-transmissive member 50 and the lateral surfaces 40c of the bonding member 40. To be specific, the uncured second covering member 62 is disposed on the first covering member 61 so as to allow the upper surface 50a of the light-transmissive member 50 to be exposed, and so as to cover the lateral surfaces 50c of the light-transmissive member 50 and the lateral surfaces 40c of the bonding member 40. The uncured second covering member 62 can be disposed on the first covering member 61 by, for example, potting, spraying, printing or compression molding. The second covering member 62 may cover the upper surface of the protective element 30 and a portion of the lateral surfaces of the protective element 30. Thereafter, the uncured second covering member 62 is cured to form the covering member 60 made up of the cured first covering member 61 and second covering member 62. Thus, the light-emitting device 1 is obtained.

Before disposing the light-emitting element 20 on the wiring substrate 10, the light-transmissive member 50 may be disposed on the upper surface 20a of the light-emitting element 20 via the first bonding members 401 and the second bonding member 402 to cure the first bonding members 401 and the second bonding member 402. Then, this structure may be disposed on the wiring substrate 10.

The method of manufacturing the light-emitting device according to the embodiment can simultaneously manufacture a plurality of the light-emitting devices 1. In this case, in the step of preparing the wiring substrate, a collective substrate is prepared, which includes a plurality of regions to be the wiring substrates 10 of the individual light-emitting devices 1 after singulation. Then, the light-emitting element 20 and the protective element 30 are disposed in each region of the prepared collective substrate. After the above-described steps, a singulation step of separating the collective substrate into individual regions is performed, whereby the light-emitting device 1 illustrated in FIG. 1 can be obtained.

As described above, in the method of manufacturing the light-emitting device 1, the uncured first bonding members 401 are disposed on at least a portion of the outer peripheral region of the upper surface 20a of the light-emitting element 20, and the uncured second bonding member 402 having the lower viscosity than the uncured first bonding members 401 is disposed on the upper surface 20a of the light-emitting element 20 exposed from the first bonding members 401. Then, the first bonding members 401 and the second bonding member 402 are pressed by the lower surface 50b of the light-transmissive member 50 to spread the first bonding members 401 and/or the second bonding member 402 in the outer peripheral region of the lower surface 50b of the light-transmissive member 50. Thus, the second bonding member 402 having the low viscosity spreads along the first bonding members 401 each having the high viscosity so as to come into contact with the corners of the lower surface 50b of the light-transmissive member 50. As a result, since the cured bonding member 40 is in contact with the entire lower surface 50b of the light-transmissive member 50, the brightness is less likely to decrease at the corners of the lower surface 50b of the light-transmissive member 50, and the light-emitting device 1 with less brightness unevenness can be manufactured.

### Modified Examples

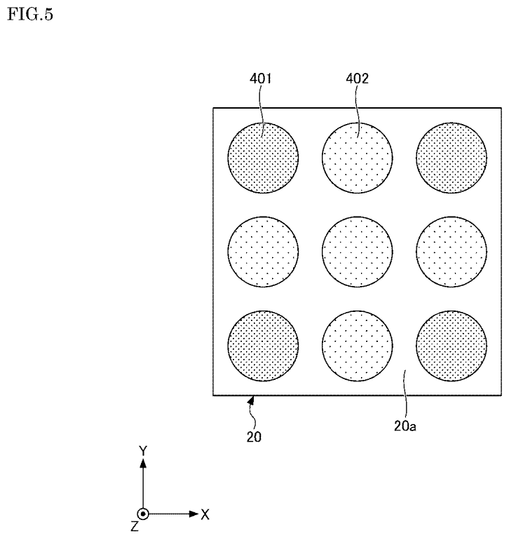

FIG. 5 is a schematic view illustrating a manufacturing process of the light-emitting device according to Modified Example 1 of the present embodiment. Specifically, FIG. 5 is a schematic view of the light-emitting element, the first bonding member, and the second bonding member as viewed from the upper surface side of the light-emitting element. In the manufacturing process of the light-emitting device according to the present embodiment, the step illustrated in FIG. 5 may be performed instead of the step illustrated in FIG. 4F.

In the step of disposing the second bonding member illustrated in FIG. 4F, the example has been described in which one uncured second bonding member 402 is disposed in the central region located inside the outer peripheral region of the upper surface 20a of the light-emitting element 20. However, the manufacturing process is not limited to this example, and as illustrated in FIG. 5, in the step of disposing the second bonding member, the uncured second bonding member 402 may be disposed in the outer peripheral region of the upper surface 20a of the light-emitting element 20, and in the central region surrounded by this outer peripheral region. In the example of FIG. 5, in addition to the central region, one uncured second bonding member 402 is disposed between adjacent corners of the outer peripheral region.

As described above, the uncured second bonding member 402 is disposed in both the outer peripheral region and the central region of the upper surface 20a of the light-emitting element 20. Thus, the second bonding member 402 can be more reliably brought into contact with the corners of the lower surface 50b of the light-transmissive member 50 in the step of spreading the first bonding member and/or the second bonding member illustrated in FIGS. 4J and 4K.

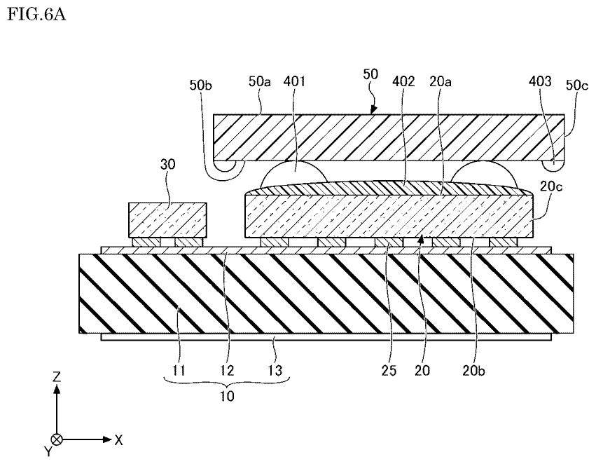

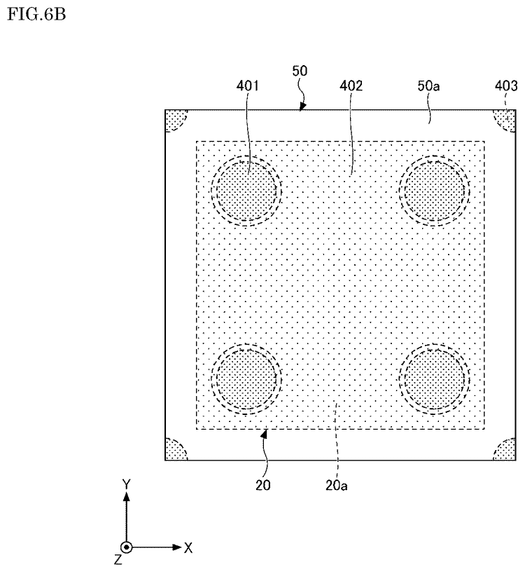

FIGS. 6A and 6B are schematic views each illustrating a manufacturing process of the light-emitting device according to Modified Example 2 of the present embodiment. Specifically, FIG. 6A is a schematic cross-sectional view illustrating an example of the manufacturing process of the light-emitting device according to Modified Example 2 of the present embodiment. FIG. 6B is a schematic view of the light-emitting element, the first bonding member, the second bonding member, and the light-transmissive member as viewed from the upper surface side of the light-transmissive member.

When the lower surface 50b of the light-transmissive member 50 has a rectangular shape, the steps illustrated in FIGS. 6A and 6B may be performed before the step of spreading the first bonding member and/or the second bonding member. In the steps illustrated in FIGS. 6A and 6B, uncured third bonding members 403 each having a higher viscosity than the uncured second bonding member 402 are disposed at the four corners of the lower surface 50b of the light-transmissive member 50. The uncured third bonding member 403 having a high viscosity is preferably selected so as not to easily creep up the lateral surfaces 50c of the light-transmissive member 50. The viscosity of the uncured third bonding member 403 can be in a range, for example, from 100 Pa·s to 450 Pa·s.

After the steps of FIGS. 6A and 6B, the same steps as those of FIGS. 4J to 4M are performed to thereby complete the light-emitting device.

As described above, in the manufacturing process of the light-emitting device according to Modified Example 2 of the present embodiment, the uncured third bonding members 403 are disposed at the four corners of the lower surface 50b of the light-transmissive member 50 before the step of spreading the first bonding member and/or the second bonding member. Thus, in the step of spreading the first bonding member and/or the second bonding member, the second bonding member 402 having reached the third bonding members 403 further spreads along the third bonding members 403, and thus easily reaches the outer peripheral portion of the lower surface 50b of the light-transmissive member 50, including the corners of the lower surface 50b. This is particularly effective when there is a significant difference in area between the lower surface 50b of the light-transmissive member 50 and the upper surface 20a of the light-emitting element 20.

The uncured third bonding member 403 may be cured before the step of spreading the first bonding members 401 and/or the second bonding member 402, or may be simultaneously cured with the first bonding members 401 and the second bonding member 402 after the step of spreading the first bonding members 401 and/or the second bonding member 402.

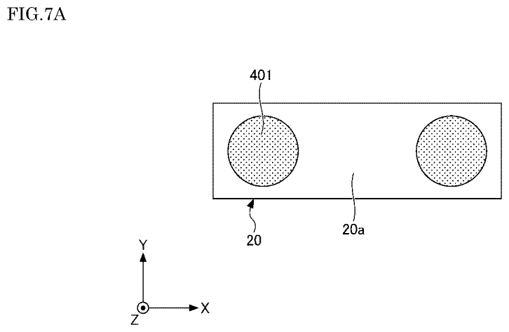

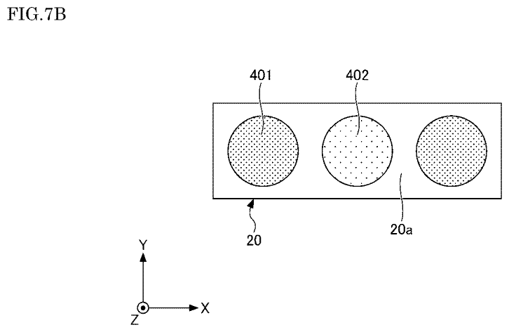

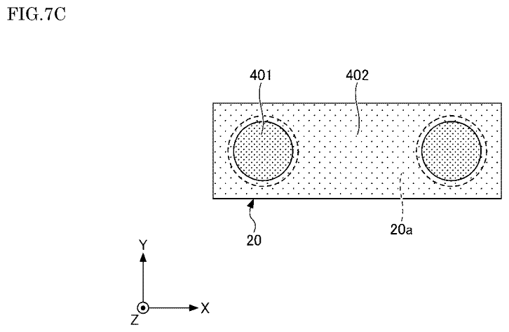

FIGS. 7A to 7C are schematic views, each illustrating a manufacturing process of the light-emitting device according to Modified Example 3 of the present embodiment. Specifically, each of FIGS. 7A to 7C is a schematic view of the light-emitting element, the first bonding members, and the second bonding member as viewed from the upper surface side of the light-emitting element. FIGS. 7A to 7C illustrate positions where the uncured first bonding members 401 and the uncured second bonding member 402 are disposed when the upper surface 20a of the light-emitting element 20 has a rectangular shape.

First, after the same steps as those in FIGS. 4A and 4B are performed, as illustrated in FIG. 7A, the uncured first bonding members 401 are disposed on at least a portion of an outer peripheral region of the upper surface 20a of the light-emitting element 20. When the upper surface 20a of the light-emitting element 20 has the rectangular shape, as an example, the uncured first bonding members 401 may be disposed in two regions close to short sides of the upper surface 20a of the light-emitting element 20 so as to be spaced apart from each other.

Next, as illustrated in FIG. 7B, the uncured second bonding member 402 having the lower viscosity than the uncured first bonding members 401 is disposed on the upper surface 20a of the light-emitting element 20 exposed from the first bonding members 401. For example, the uncured second bonding member 402 is disposed in a central region interposed between the first bonding members 401 facing each other so as not to be in contact with the first bonding members 401.

Since the uncured second bonding member 402 has the low viscosity, it spreads from the discharge position to the periphery and reaches the two first bonding members 401. The second bonding member 402 having reached the first bonding members 401 further spreads along the first bonding members 401, and finally spreads over the entire upper surface 20a as illustrated in FIG. 7C. The second bonding member 402 may creep up a skirt portion of the first bonding members 401, or may creep up the entire surface of the first bonding members 401.

After the step of the FIG. 7C, the same steps as those of FIGS. 4I to 4M are performed to thereby complete the light-emitting device. As described above, the method of manufacturing a light-emitting device according to the present disclosure is also applicable to a light-emitting device whose upper surface has a rectangular shape.

Preferred embodiments and the like have been described in detail above. However, the invention is not limited to the above-described embodiments and the like, and various modifications and substitutions can be made to the above-described embodiments and the like without departing from the scope described in the claims.

What is claimed is:

1. A method of manufacturing a light-emitting device, the method comprising:
preparing a light-emitting element;
preparing a light-transmissive member, wherein an area of a lower surface of the light-transmissive member is larger than an area of an upper surface of the light-emitting element;
disposing a first bonding member that is uncured on at least a portion of an outer peripheral region of the upper surface of the light-emitting element;
disposing a second bonding member that is uncured on a portion of the upper surface of the light-emitting element that is exposed from the first bonding member, wherein a viscosity of the second bonding member that is uncured is lower than a viscosity of the first bonding member that is uncured;
spreading the first bonding member and/or the second bonding member in an outer peripheral region of the lower surface of the light-transmissive member by pressing the first bonding member and the second bonding member by the lower surface of the light-transmissive member; and
curing the first bonding member and the second bonding member.

2. The method of manufacturing a light-emitting device according to claim 1, wherein:
in the step of spreading the first bonding member and/or the second bonding member, the first bonding member and/or the second bonding member covers a lateral surface of the light-emitting element.

3. The method of manufacturing a light-emitting device according to claim 1, wherein:
in the step of spreading the first bonding member and/or the second bonding member, the first bonding member and/or the second bonding member reaches an outer edge of the lower surface of the light-transmissive member.

4. The method of manufacturing a light-emitting device according to claim 1, wherein:
the upper surface of the light-emitting element is rectangular, and
in the step of disposing the first bonding member, the first bonding member and one or more additional first bonding members that are uncured are respectively disposed at four corners of the upper surface of the light-emitting element to be spaced apart from each other.

5. The method of manufacturing a light-emitting device according to claim 4, wherein:
in the step of disposing the second bonding member, the second bonding member that is uncured is disposed in a central region located inside the outer peripheral region of the upper surface of the light-emitting element.

6. The method of manufacturing a light-emitting device according to claim 4, wherein:
in the step of disposing the second bonding member, the second bonding member that is uncured is disposed on a portion of the outer peripheral region of the upper surface of the light-emitting element and in a central region surrounded by the outer peripheral region of the upper surface of the light-emitting element.

7. The method of manufacturing a light-emitting device according to claim 1, wherein:
a viscosity of the first bonding member that is uncured is in a range from 30 Pa s to 120 Pa·s.

8. The method of manufacturing a light-emitting device according to claim 1, wherein:
a viscosity of the second bonding member that is uncured is in a range from 0.1 Pa·s to 15 Pa·s.

9. The method of manufacturing a light-emitting device according to claim 1, wherein:
a volume of the second bonding member that is uncured and disposed on the upper surface of the light-emitting element in the step of disposing the second bonding member is larger than a volume of the first bonding member that is uncured and disposed on the upper surface of the light-emitting element in the step of disposing the first bonding member.

10. The method of manufacturing a light-emitting device according to claim 1, wherein:
a lower surface of the light-transmissive member is rectangular, and
before the step of spreading, third bonding members that are uncured are disposed at four corners of the lower surface of the light-transmissive member, wherein a viscosity of each of the third bonding members is higher than the viscosity of the second bonding member that is uncured.

11. The method of manufacturing a light-emitting device according to claim 1, wherein:
in the step of spreading, the first bonding member and one or more additional first bonding members are respectively in contact with an outer edge of the upper surface of the light-emitting element at four corners of the upper surface of the light-emitting element in a top view.

12. The method of manufacturing a light-emitting device according to claim 1, wherein:
in the step of spreading, corners of the lower surface of the light-transmissive member are in contact with the second bonding member.

13. The method of manufacturing a light-emitting device according to claim 1, wherein:
in the step of spreading, the second bonding member is disposed in an entire region interposed between the upper surface of the light-emitting element and the lower surface of the light-transmissive member.

14. The method of manufacturing a light-emitting device according to claim 1, wherein:
the first bonding member and the second bonding member each contains light scattering particles and a resin,
a concentration of the light scattering particles in the first bonding member is higher than a concentration of the light scattering particles in the second bonding member.

15. The method of manufacturing a light-emitting device according to claim 1, further comprising:
disposing the light-emitting element on a wiring substrate.

16. The method of manufacturing a light-emitting device according to claim 15, wherein:
the step of disposing the light-emitting element is performed after the step of curing the first bonding member and the second bonding member.

17. The method of manufacturing a light-emitting device according to claim 1, further comprising:
after the step of disposing the light-emitting element, disposing a covering member that covers a lateral surface of the light-transmissive member, a lateral surface of the first bonding member and a lateral surface of the second bonding member, and a lateral surface of the light-emitting element, while allowing the upper surface of the light-transmissive member to remain exposed from the covering member.

18. The method of manufacturing a light-emitting device according to claim 1, wherein:
the light-transmissive member contains a phosphor.
